(19) United States
(12) Patent Application Publication
(10) Pub. No.: US 2026/0202439 A1
(43) Pub. Date: Jul. 16, 2026

(54) PROBE HEAD FOR A TESTING APPARATUS OF ELECTRONIC DEVICES

(71) Applicant: TECHNOPROBE S.P.A., Cernusco Lombardone (LC) (IT)

(72) Inventors: Stefano FELICI, Cernusco Lombardone (LC) (IT); Fabio MORGANA, Cernusco Lombardone (LC) (IT)

(73) Assignee: TECHNOPROBE S.P.A., Cernusco Lombardone (LC) (IT)

(21) Appl. No.: 19/136,600

(22) PCT Filed: Oct. 30, 2023
(86) PCT No.: PCT/EP2023/080265

§ 371 Date: Jun. 6, 2025

(30) Foreign Application Priority Data
Dec. 21, 2022 (IT) 102022000026178

(51) Int. Cl. G01R 1/073; G01R 1/04; G01R 1/067; H05K 7/20

(52) U.S. Cl. CPC G01R 1/07314; G01R 1/04; G01R 1/0675; G01R 1/06766; H05K 7/20418

(57) ABSTRACT

It is herein described a probe head including at least one guide and a plurality of contact probes housed in a plurality of guide holes formed in the at least one guide, the plurality of contact probes being configured to abut onto a plurality of contact pads of a device under test, as well as at least one housing element configured to enclose the contact probes, further including a heat dispersion structure configured to collect and dissipate heat produced by the probe head and by the contact probes therein contained during test operations of the electronic device, the heat dispersion structure including at least one layer having thermal conductivity greater than 100 W/(m·K).

### TECHNICAL FIELD

The present invention relates to a probe head adapted to be mounted in a probe card of a testing apparatus of electronic devices.

The invention relates in particular, but not exclusively, to a probe head equipped with a plurality of contact probes housed in guide holes of at least one guide and adapted to abut onto contact pads of a device under test and the following description is made with reference to this field of application with the sole aim of simplifying the exposure thereof.

### BACKGROUND ART

As it is well known, a probe card is essentially a device adapted to electrically connect a plurality of contact pads of a microstructure, in particular an electronic device that is integrated on a wafer, with corresponding channels of a testing apparatus that performs the functionality testing thereof.

The test, which is performed on integrated devices, is particularly useful for detecting and isolating defective devices as early as in the production phase. Usually, probe cards are therefore used for the electrical test of devices integrated on a wafer or chips before cutting and assembling them inside a chip containment package.

A probe card comprises a probe head, in turn essentially including a plurality of movable contact elements or contact probes equipped with at least one end portion or contact tip adapted to abut onto a corresponding plurality of contact pads of the device under test. The terms “end” or “tip” hereinafter indicate an end portion of said probes, which is not necessarily pointed.

It is well known that the effectiveness and reliability of a measuring test depend, amongst the other factors, precisely on a good electrical connection between device under test and testing apparatus, and therefore on the establishment of an optimal probe/pad electrical contact.

Among the types of probe heads used in the technical field herein considered for testing devices integrated on a wafer, the so-called vertical probe heads are widely spread, in which the contact probes are arranged substantially perpendicular with respect to a plane whereon the device under test lies.

In particular, a vertical probe head comprises a plurality of contact probes held by at least one plate or guide, usually a pair of plates or guides, which are substantially plate-shaped and parallel to each other. Said guides are arranged at a certain distance from each other in order to leave a free space or air gap for the movement and possible deformation of the contact probes during the test operations and are equipped with suitable guide holes adapted to slidingly house said contact probes. More particularly, the pair of guides comprises an upper guide (upper die) and a lower guide (lower die), both provided with guide holes within which the contact probes axially slide, usually formed by wires of special alloys with good electrical and mechanical properties and in the field also indicated as needles, the term “lower” conventionally indicating the guide which is closest to the device under test.

The good connection between the contact probes of the probe head and the contact pads of the device under test is ensured by the pressure of the probe head on the device itself, the contact probes, which are movable within the guide holes formed in the upper and lower guides, undergoing, during said pressing contact, a bending inside the air gap between the two guides and a sliding inside the guide holes housing them.

The bending of the contact probes in the air gap may also be facilitated and guided through a suitable configuration of the probes themselves or of the guides, in particular using pre-deformed contact probes or suitably transversally shifting the guides comprising them, the transversal direction being the one substantially parallel to the plane of the device under test and of the guides.

In general, probe heads with not fixedly fastened probes but held interfaced to a suitable main plate or main board, in turn connected to the testing apparatus, are used: such probe heads are referred to as unblocked probe heads. Said main board is also indicated as main board or main PCB (Printed Circuit Board), since it is usually made by using the printed circuit techniques, a technology that allows making boards with active areas, namely provided with contact pads, even large ones, albeit with major limitations compared to an achievable minimum value for the distance (pitch) between the centers of the contact pads and therefore usually reserved for making said main board, indeed, whose distance constraints between pads are more relaxed compared to the device under test.

This relaxation of the distance constraints between contact pads, and in particular the distancing of adjacent pads on the main board, is possible thanks to the use of an intermediate board or space transformer which has contact pads made on opposite faces thereof with centers at a different distance between a face and the opposite one, suitably connected to each other thanks to connections, in particular metal traces, formed inside the space transformer itself.

In this case, the contact probes have a further end portion or contact head adapted to abut onto a plurality of contact pads formed on a first face of said space transformer, in particular a face arranged toward the probe head and thus the device under test. The good electrical connection between contact probes and space transformer is ensured analogously to the contact with the device under test by the pressure of the probes onto the contact pads formed on the space transformer.

Furthermore, the main board is generally kept in position by a stiffener. The assembly constituted by probe head, main board, intermediate board or space transformer and stiffener forms a probe card, wholly and schematically indicated with reference number 10 in FIG. 1.

In particular, the probe card 10 thus comprises a probe head 1, in the figure example comprising a plurality of vertical probes 2 and at least one upper guide 4 and one lower guide 5, having respective upper guide holes 4A and lower guide holes 5A within which the contact probes 2 slide.

Each contact probe 2 has at least one first end portion or contact tip 2A that abuts onto a contact pad 3A of a device under test 3 integrated on a semiconductor wafer 3′, realizing the mechanical and electrical contact between the device under test and a testing apparatus (not represented) which said probe head 1 is an end element of.

Moreover, each contact probe 2 has a second end portion, in the field referred to as contact head 2B, between the contact tip 2A and the contact head 2B, the probe body 2C extending according to a longitudinal development axis of the contact probe 2, said longitudinal development axis being substantially orthogonal to a plane of the device under test and thus to the guides.

In turn, the contact head 2B is adapted to perform the contact with a plurality of contact pads 6A formed on an intermediate board, which acts in particular as space transformer 6 and is connected to a main plate or main board 7, in turn connected to the testing apparatus.

The spatial transformation realized by the space transformer 6 relates in particular to the distances between the centers of the contact pads formed on opposite faces thereof; said space transformer 6 comprises a first plurality of contact pads 6A formed on a first face FA thereof facing toward the probe head 1, arranged at the contact heads 2B of the contact probes 2 and connected by suitable metallizations 6C to a second plurality of contact pads 6B formed on a second opposite face FB thereof facing toward the main board 7, said second plurality of contact pads 6B having a different spatial distribution, in particular with centers of the pads at a greater distance, namely greater pitch compared to the pitch of the first plurality of contact pads 6A, which instead are distributed in a substantially corresponding manner to the contact pads 3A of the device under test 3. In this way, the space transformer 6 realizes the spatial transformation, by moving away the contact pads 6B formed on the second face FB thereof with respect to the contact pads 6A formed on the first face FA thereof. They are commonly referred to as probe side pad or fine pitch and as PCB side pad or large pitch to indicate the contact pads 6A of the first plurality and the contact pads 6B of the second plurality, respectively.

The good electrical connection between contact probes 2 and space transformer 6 is ensured analogously to the contact with the device under test 3 by the pressure of the probes on the contact pads 6A formed on the first face FA of the space transformer 6.

As already indicated, the main board 7 is also kept in position by a stiffener 8, which is configured so as to make the whole assembly more rigid and resistant and allows reducing the flatness defects, in particular in connection to the space transformer 6, which generally has very reduced thicknesses and thus significant flatness issues.

In the embodiment illustrated in FIG. 1, the probe head 1 comprises a further intermediate guide 5′ (medium guide), which is plate-shaped and parallel to the upper guide 4 and to the lower guide 5 and arranged therebetween, preferably close to the lower guide 5, the intermediate guide 5′ being in turn provided with a plurality of intermediate guide holes 5′A in which the contact probes 2 are slidingly housed.

Suitably, the upper guide 4, the lower guide 5 and the intermediate guide 5′ are shifted with respect to each other, with respect to a transversal direction corresponding to the x axis of the local reference of FIG. 1, so as to ensure a preferential bending direction to the contact probes 2, in addition to a proper holding thereof inside the probe head 1, completed by a container (housing) 9 which makes the guides integral to each other.

In the vertical probe technologies, it is thus important to ensure the good connection of the contact probes with the device under test, in particular at the contact tips thereof, and with the testing apparatus, in particular at the contact heads thereof and thus at the space transformer, which plays a very important role especially in the test operations of integrated circuits made according to the most recent integration technologies which involve contact pads on the devices under test which are extremely close to each other and very small in size, constraints that are poorly compatible with the PCB technology through which the main board of the probe card is formed.

The mutual positioning of the elements that make up the probe card is an extremely important parameter for a proper operation of the card itself and the several technologies used to make said elements introduce flatness issues that complicate the configuration of the card as a whole and especially in relation to the mutual positioning of intermediate board or space transformer and main board. Even the presence of the stiffener, which makes the whole thing more rigid and resistant, generally does not allow sufficiently eliminating the flatness defects of the space transformer and ensuring the proper and complete contact thereof with the main board.

The whole situation is further complicated by the operating temperature of the probe card itself, in particular in case of tests performed at extreme temperatures. In this case, indeed, the thermal expansion of the elements that make up the probe card may affect its correct behavior, due to the different thermal expansion coefficients of the different materials these elements are made up of. Indeed, it is usual to fasten together the elements that make up a probe card by using screws, which, particularly during the test operations at temperature, apply a constraint to the different boards which tends to cause them to buckle, resulting in a malfunction of the probe card as a whole, at the limit even with the lack of contact of the contact probes of the probe head with the contact pads of the device under test.

This problem is particularly felt in case of large sized probe cards, such as for instance the probe cards for test operations of memory devices such as the DRAMs. For this kind of probe cards, failure to control the thermal expansion of the components causes significant issues in the test phase.

Moreover, during the test operations, the contact probes heat up due to the passage of the several signals, thus increasing the heat present inside the probe head, in particular in case of a probe head equipped with a very high number of contact probes.

The technical problem of the present invention is to provide a probe head having functional and structural features such as to allow overcoming the limitations and drawbacks still affecting the probe heads made according to the known technologies, thus favoring the elimination of the heat that is produced during the test operations and limiting the increase in the temperature at which the probe head itself and also the probe card including it work.

### DISCLOSURE OF INVENTION

The solution idea underlying the present invention is to equip a probe head of a structure that dissipates the heat generated by the test operations, preferably through dissipation in air, so as to limit the increase in the operating temperature of the probe head, in order to avoid deformations and therefore malfunctions of the probe head itself and of the probe card including it.

Based on this solution idea, the technical problem is solved by a probe head comprising at least one guide and a plurality of contact probes housed in a plurality of guide holes formed in said at least one guide, the plurality of contact probes being adapted to abut onto a plurality of contact pads of a device under test, as well as at least one housing element adapted to enclose said contact probes. Suitably, the probe head further comprises a heat dispersion structure able to collect and dissipate the heat produced by said probe head and by the contact probes therein contained during the test operations of the electronic device. Furthermore, the heat dispersion structure comprises at least one layer having thermal conductivity greater than 100 W/(m·K).

More particularly, the invention comprises the following additional and optional features, taken singularly or in combination if needed.

According to an aspect of the invention, the layer may be selected from: a coating layer arranged along at least one face of the at least one guide, a lateral coating layer of the housing element, a covering layer of the at least one guide that comprises at least one lateral portion extending along a lateral wall of the at least one guide and at least one planar portion extending along a further face of the at least one guide, said further face being orthogonal to the lateral wall, and a full covering layer of the housing element.

According to another aspect of the invention, the layer may comprise at least one portion in contact with air.

Still according to another aspect of the invention, the layer may be made of a material having thermal conductivity greater than 500 W/(m·K).

Furthermore, the layer may be made of a material having electrical resistivity greater than 10⁴ Ω·m, preferably greater than 10¹⁶ Ω·m.

More particularly, according to another aspect of the invention, the layer may be made of a material selected from silicon nitride, silicon carbide and CVD-D (Chemical Vapor Deposition-Diamond), preferably CVD-D.

According to another aspect of the invention, the layer may be formed at a face of the at least one guide. Preferably, said layer may be formed outside an active zone of the at least one guide where guide holes for housing the contact probes are present.

According to a further aspect of the invention, the layer may have a thickness comprised between 50 and 500 microns, preferably equal to 150 microns.

Moreover, the layer may be formed at a face of the at least one guide even at an active zone of the at least one guide where guide holes for housing said contact probes are present. In this case, the probe head may be provided with electrical decoupling structures between the contact probes and the layer. Suitably, the electrical decoupling structures may be selected from a dielectric coating which covers portions of the contact probes in contact with the layer, clipping areas free from the layer along the edges of the guide holes for housing the contact probes.

According to another aspect of the invention, the heat dispersion structure may further comprise an outer heat dissipator, thermally connected to the layer.

More particularly, the heat dissipator may peripherally surround the probe head.

According to another aspect of the invention, the heat dispersion structure may further comprise a forced-air supply structure adapted to convey air into the probe head. Preferably, the air may be conveyed at the layer.

Finally, according to another aspect of the invention, the forced-air supply structure may produce a forced-air flow at a portion of the layer outside an active zone of the at least one guide where guide holes for housing the contact probes are present.

The technical problem is also solved by a probe card adapted to be mounted in a testing apparatus of electronic devices, said probe card comprising at least one probe head made as above indicated.

According to another aspect of the invention, the probe card may further comprise a heat dispersion device provided with at least one active or passive thermal pipe in thermal contact with a space transformer of the probe card so as to increase a dispersion of the heat generated inside the probe head during the operation thereof.

The features and advantages of the probe head and of the probe card according to the invention will become apparent from the following description of embodiments thereof, given by way of indicative and non-limiting example, with reference to the attached drawings.

### BRIEF DESCRIPTION OF DRAWINGS

In these drawings:

FIG. 1 shows a schematic sectional view of a probe card comprising a vertical probe head made according to the prior art;

FIG. 2A shows a schematic sectional view of a probe card comprising a vertical probe head according to an embodiment of the invention;

FIGS. 2B-2D show a schematic sectional view of a probe card comprising a vertical probe head according to alternative embodiments of the invention; and

FIGS. 3A-3B, 4A-4C, 5A-5C and 6 show respective sectional, plan and side views of a probe card comprising a vertical probe head according to further alternative embodiments of the invention.

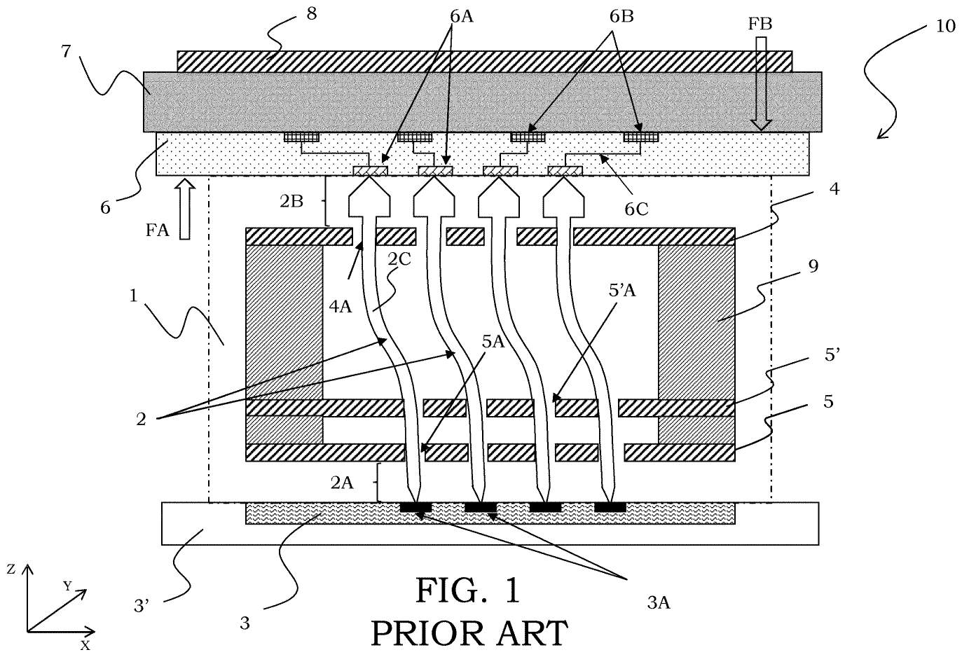

### MODES FOR CARRYING OUT THE INVENTION

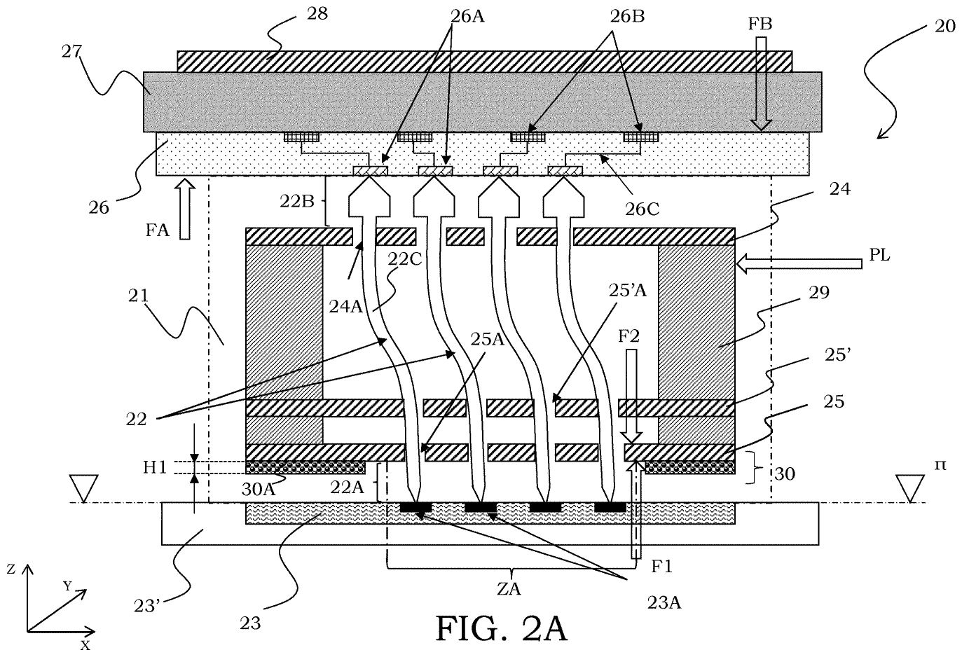

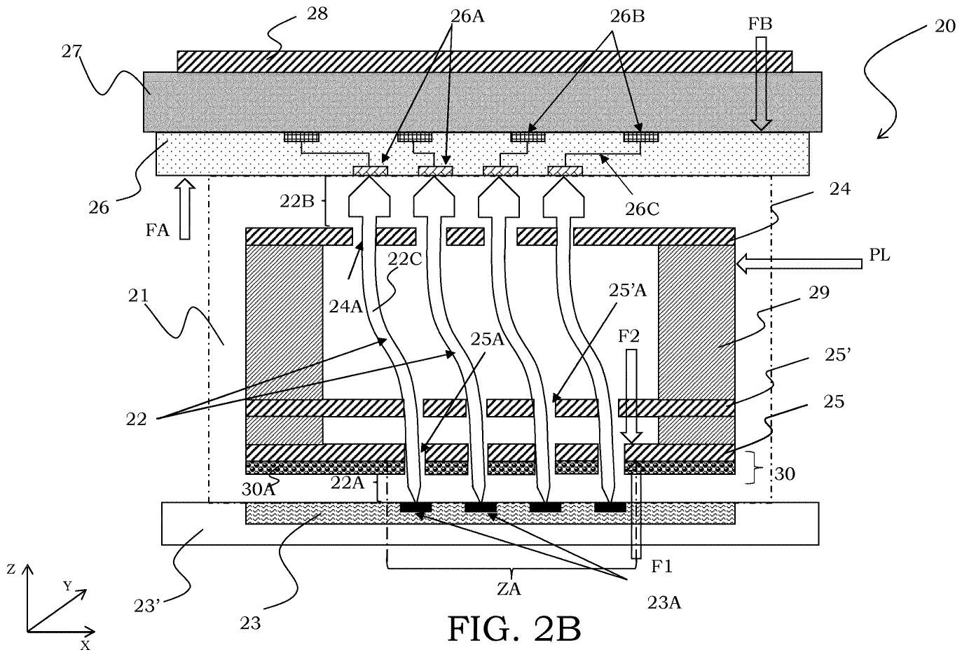

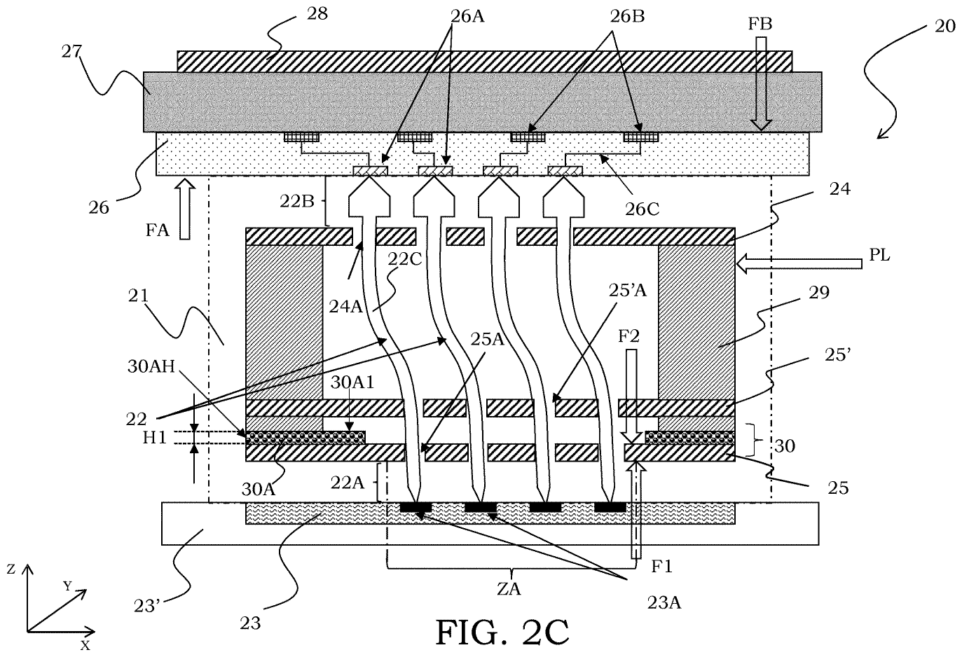

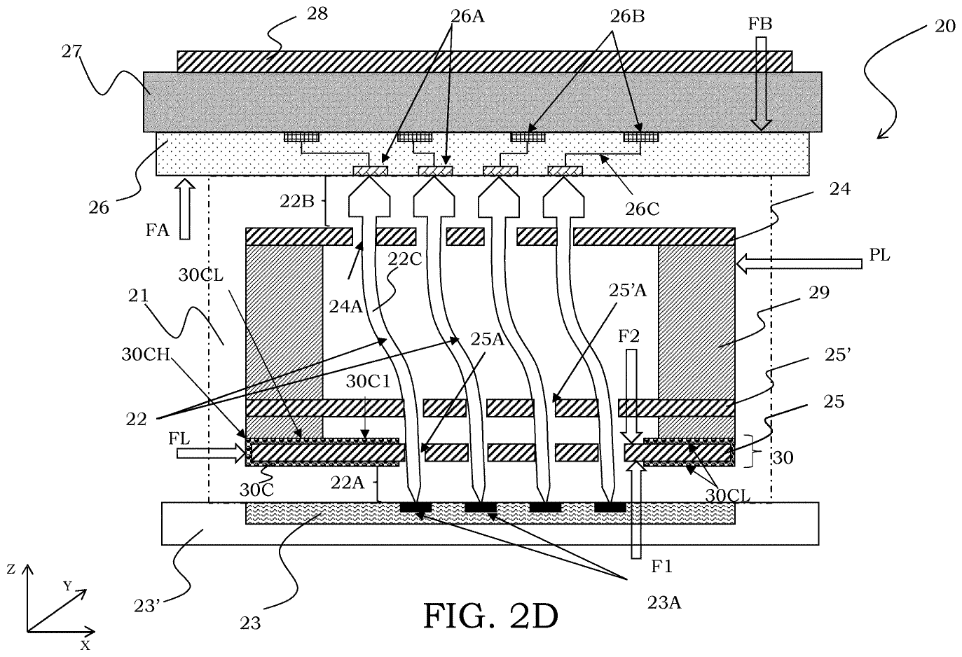

With reference to these figures, and particularly to FIG. 2A, reference number 20 globally indicates a probe card comprising at least one probe head provided with a plurality of contact probes for testing electronic devices, in particular integrated on wafers, made according to the present invention.

It should be noted that the figures are schematic views of the probe card and are not drawn to scale, but instead they are drawn so as to enhance the important features of the invention.

Moreover, the several aspects of the invention represented by way of example in the figures can obviously be combined with each other and are interchangeable from one embodiment to another.

Furthermore, elements that are structurally and functionally the same in the several embodiments illustrated in the various figures and described hereinafter are indicated with the same alphanumeric references.

In the following description, relative terms such as “on”, “under”, “upward”, “downward”, “upper”, “lower” will be used referring to the illustrations of the solutions given in the figures just to simplify the exposure thereof.

Finally, indications of particular geometries (circular, rectangular) or of the arrangement of the elements (parallel, orthogonal, contiguous), as well as the term “substantially”, are always to be intended in connection to physical elements and not as geometrically abstract elements, therefore they must always take into consideration the tolerances introduced by the transition from a pure mathematical/geometric world to the real world.

In particular, as illustrated in FIG. 2A, the probe card 20 comprises a probe head 21 that houses a plurality of contact probes 22. The probe head 21 illustrated is a non-blocked vertical probe head and comprises at least one upper plate or guide 24 and one lower plate or guide 25, having respective upper guide holes 24A and lower guide holes 25A within which the contact probes 22 slide.

As it is conventional in the technical field of the present invention, the term “lower guide” indicates the guide arranged closest to a device under test and the term “upper guide” indicates the guide arranged closest to a testing apparatus connected to the probe card 20 that includes the probe head 21, when said probe card 20 and thus the probe head 21 is in the operating conditions, mounted as an end element of said testing apparatus.

The probe head 21 also comprises a containment element or housing 29, adapted to enclose the contact probes 22 and to make the upper guide 24 and the lower guide 25 integral to each other.

In the example illustrated in FIG. 2A, the probe head 21 also comprises an intermediate plate or guide 25′, arranged parallel between the upper guide 24 and the lower guide 25, in particular closer to the latter, the intermediate guide 25′ also being provided with intermediate guide holes 25′A within which the contact probes 22 slide. Said three-guide embodiment is only given by way of indicative example, the probe head 21 being able to comprise any number of guides greater than or equal to one.

Each of the contact probes 22 comprises at least one first end portion or contact tip 22A adapted to abut onto a corresponding contact pad 23A of a device under test 23, in particular integrated on a semiconductor wafer 23′, so as to establish the desired contact, in particular an electrical contact, between the contact probes 22 of the probe head 21 and the contact pads 23A of the device under test 23.

Each contact probe 22 further comprises a second end portion or contact head 22B adapted to realize the contact with a main plate 27 or main PCB for connection with a testing apparatus (not illustrated). Between the contact head 22B and the contact tip 22A a rod-shaped probe body 22C is arranged, substantially according to a longitudinal development direction of the contact probe 22, in particular orthogonal to a plane π whereon the semiconductor wafer 23′, where the device under test 23 is integrated, is arranged, i.e., along the z axis of the local reference of FIG. 2A.

The upper guide 24, the lower guide 25 and the intermediate guide 25′ are plate-shaped elements arranged parallel to each other and to the plane π of the semiconductor wafer 23′ and thus of the device under test 23. Suitably, as seen in connection to the prior art, said upper guide 24, lower guide 25 and intermediate guide 25′ are shifted to one another, with respect to a direction that is tangential to the plane π of the semiconductor wafer 23′, i.e., according to the x axis of the local reference of FIG. 2A, so as to impose a preferential bending direction to the contact probes 22. Due to this shift of the guides, the guide holes formed therein and housing a same contact probe turn not to be aligned to each other with respect to a direction orthogonal to the plane π of the semiconductor wafer 23′, i.e., according to the z axis of the local reference of FIG. 2A, which forces a bending in the probe body 22C of the contact probes 22 and determines said preferential bending direction thereof.

The probe card 20 further comprises an intermediate board arranged between the probe head 21 and the main board 27 and adapted to perform a spatial transformation, in particular in connection to the distribution of contact pads on the opposite faces thereof and for this reason indicated as space transformer 26.

The space transformer 26 has a first face FA facing toward the probe head 21 (in the operating conditions, i.e., when the space transformer 26 is inserted in a probe card 20 comprising the contact head 21 and mounted as end element of a testing apparatus), on said first face FA a first plurality of contact pads being formed, also indicated as probe side pads 26A, whereonto the contact heads 22B of the contact probes 22 abut. Furthermore, the space transformer 26 has a second face FB, opposite the first face FA and thus facing (in the operating conditions) toward the main board 27 for connecting with the testing apparatus, said second face FB in turn comprising a second plurality of contact pads, also indicated as tester side pads 26B, connected to the plurality of probe side pads 26A by means of respective electrical connections 26C made inside the space transformer 26. Suitably, the tester side pads 26B may be larger in size and arranged with respect to each other at a greater distance with respect to the probe side pads 26A, the space transformer 26 thus realizing the desired spatial transformation.

Finally the probe card 20 comprises a stiffener 28 associated with the main board 27 and adapted to improve the flatness thereof and to avoid the bending thereof, in particular in case of an increase in temperature during the operation of the probe card 20, i.e., during the test operations.

Advantageously according to the present invention, the probe head 21 comprises at least one heat dispersion structure 30, suitably able to collect and dissipate the heat developed by the probe head 21 and by the contact probes 22 therein contained during the test operations of a device under test 23, preferably by dissipation in air.

In particular, the heat dispersion structure 30 collects the heat developed in the probe head 21, for instance due to the friction of the contact probes 22 that slide in the guide holes of at least one of the guides comprised in the probe head 21 or due to the signals that cross said contact probes 22 and that can raise the temperature thereof, for instance the so-called power signals and favors their dispersion in the environment surrounding the probe card 20 which comprises the probe head 21, preferably by dissipation in air.

In a preferred embodiment, said heat dispersion structure 30 thus has at least one portion in contact with air, in particular with the environment surrounding the probe head 21.

In the embodiment illustrated in FIG. 2A, the heat dispersion structure 30 comprises a coating layer 30A made of a high thermal conductivity material A, namely greater than 100 W/(m·K), preferably greater than 500 W/(m·K). In particular said high thermal conductivity λ allows obtaining optimal collection and subsequent dispersion of the heat produced by the probe head 21 during the test operations, thus keeping the increase in the operating temperature of said head limited, and reducing the risk of deformations to a minimum, in particular bending of the elements that make up the probe head 21 and the probe card 20 that includes it.

In other words, the coating layer 30A made of a high thermal conductivity material A which forms the heat dispersion structure 30 ensures a correct operating of the probe head 21 and of the probe card 20 as a whole during the test operations, even in the case of test operations that cause the heat production inside the probe head 21.

Preferably, the coating layer 30A is made so as to be at least partially in contact with the environment surrounding the probe head 21 when in the operating conditions.

Suitably, the high thermal conductivity material A the coating layer 30A is made of also has a high electrical resistivity p, namely greater than 10⁴ Ω·m, preferably greater than 10¹⁶ Ω·m. In this way, the presence of the coating layer 30A forming the heat dispersion structure 30 does not affect the electrical behaviour of the probe head 21 and thus of the probe card 20 and in particular does not interfere with the operation of the contact probes 22.

In a preferred embodiment, the coating layer 30A is made of silicon nitride, silicon carbide and CVD-D (Chemical Vapor Deposition-Diamond), more preferably CVD-D.

Said preferred materials are in particular able to make structures with reduced thicknesses, in particular below 500 microns, more preferably below 250 microns, while maintaining the heat dissipation properties of the dissipative structures thus obtained high.

In the embodiment illustrated in FIG. 2A, the coating layer 30A is made at a face of at least one of the guides, in particular the lower guide 25, preferably on a first face F1 facing toward the device under test 23 when the probe head 21 is in the operating conditions, also indicated as lower face F1 using the local reference of the figure and the terminology typically used in the technical field of the invention. In this way, the entire coating layer 30A is exposed to the environment surrounding the probe head 21, thus favoring the dissipation of the heat produced therein into the air.

The coating layer 30A has a thickness H1 according to the z axis of the local reference of the figure, namely in a direction orthogonal to the development plane π of the device under test 23 and thus to the guides, comprised between 50 and 500 microns, preferably equal to 150 microns.

The coating layer 30A is preferably arranged outside a so-called active zone ZA of the respective guide where guide holes for housing the contact probes 22 are present, in particular a peripheral zone where said guide holes are not present, in the example of FIG. 2A a zone of the lower guide 25 where the lower guide holes 25A are not present. In this way, suitably, a coating layer 30A, even if made of a material having conductive properties, does not interfere anyway with the usual operation of the contact probes 22.

It is also possible to make the coating layer 30A forming the heat dispersion structure 30 so as to entirely cover a face of a guide, for instance the lower guide 25 as shown in FIG. 2B, the coating layer 30A also extending in the active zone ZA where the guide holes housing the contact probes 22 are formed.

Should said coating layer 30A that entirely covers the guide be made of an even slightly conductive material, electrical decoupling structures may be suitably provided between the contact probes 22 and said conductive coating layer 30A, such as a dielectric coating that covers the portions of the contact probes 22 that may come into contact with the coating layer 30A of the heat dispersion structure 30, thus ensuring the correct operation of the probe head 21 as a whole. Alternatively, the so-called clipping areas for the guide holes may be provided, i.e., said coating layer 30A is made so as not to reach the edges of the guide holes for housing the contact probes 22, in particular the lower guide holes 25A of the lower guide 25 whereon said coating layer 30A is formed, said guide holes having an area about the edge thereof which is devoid of this coating layer 30A so as to avoid any possible electrical interference with the contact probes 22.

It is also possible to make the coating layer 30A at a different face of a guide, as illustrated in FIG. 2C, for instance at a second face F2 of the lower guide 25 facing toward the testing apparatus in normal operating conditions of the probe head 21, also indicated as upper face F2 using the local reference of FIG. 2C. In this case, the coating layer 30A may only extend outside the active zone ZA, as illustrated in FIG. 2C, or completely cover the related guide, in particular the lower guide 25, in this case providing insulating coatings for the probes at least in the portions housed in the lower guide holes 25A or possible clipping areas around said guide holes. Suitably, the coating layer 30A is made so as to extend up to an outer lateral portion PL of the probe head 21, so as to have at least one lateral portion 30AH in contact with the air of the environment surrounding the probe head 21. Furthermore, the coating layer 30A preferably extends on the lower guide 25 outside the housing element 29 up to the active zone ZA, so as to have at least one portion 30A1 exposed to air, in this case inside the probe head 21.

Though not illustrated in the figures, the heat dispersion structure 30 may be made so as to comprise a plurality of coating layers 30A formed at one or more faces of one or more of the guides of the probe head 21, such as the upper guide 24, the lower guide 25 and the intermediate guide 25′, the heat dispersion structure 30 thus may comprise one to six coating layers 30A in correspondence of one or more of said three guides. In general, it is possible to make the probe head 21 with any number of guides, greater than one, equipped or not with coating layers 30A on one or both faces thereof. Furthermore, said coating layers 30A may only extend outside the active zone of each guide or proceed inside said active zone, even entirely covering the guide, using clippings of the guide holes or further measures for the electrical decoupling with the contact probes 22 in the event one or more of the coating layers 30A are made of a conductive material.

Suitably, in a preferred embodiment, all of the layers of the heat dispersion structure 30 are formed so as to have at least one portion exposed to air, inside the probe head 21 or in the environment surrounding the same, so as to ensure collecting the heat produced inside the probe head 21 and its subsequent dissipation into the air.

According to an alternative embodiment, the heat dispersion structure 30 may comprise a covering layer 30C of at least one of the guides comprised in the probe head 21, said covering layer 30C having a lateral portion 30CH extending along a lateral wall FL of the guide, namely a wall orthogonal to the development plane π of the device under test 23, which thus is exposed to air. The covering layer 30C also comprises at least one planar portion 30CL extending along one of the faces of said guides that are parallel to said plane π, preferably both faces as shown in FIG. 2D, namely along the first face or lower face F1, and along the second opposite face or upper face F2, using the local reference of FIG. 2D. In a preferred embodiment, the covering layer 30C comprises, at the upper face F2 of the guide, a portion 30C1 exposed to air inside the probe head 21 itself.

In the example of FIG. 2D, the covering layer 30C extends only outside the active zone ZA of the lower guide 25, but it is possible to make said layer so as to entirely cover the guide, by using insulation measures for the probes should said covering layer 20C be made of a conductive material.

In an alternative embodiment, the heat dispersion structure 30 may be associated with the housing element or housing 29 of the probe head 21.

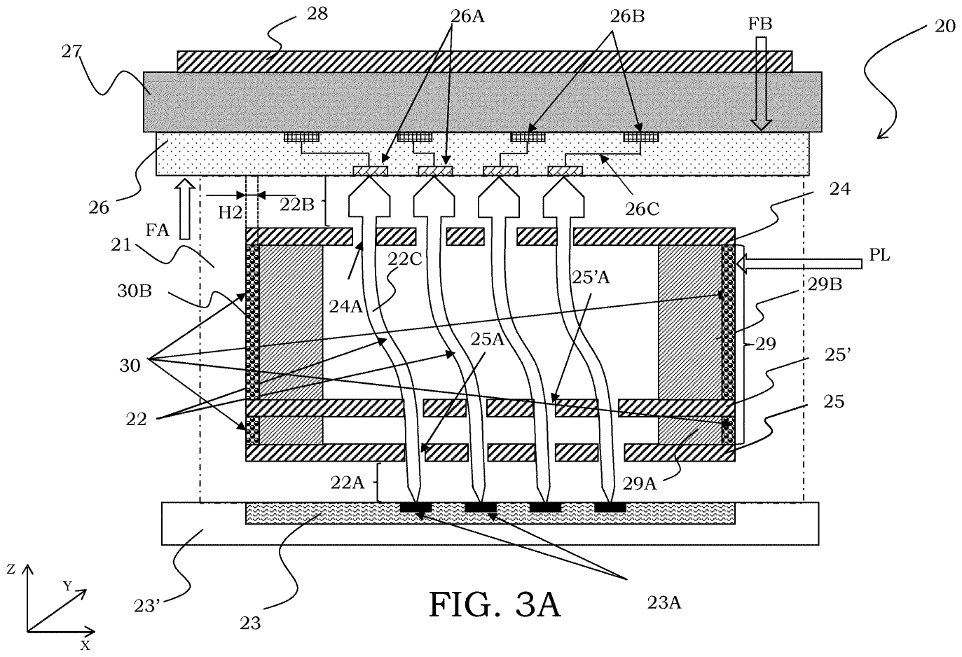

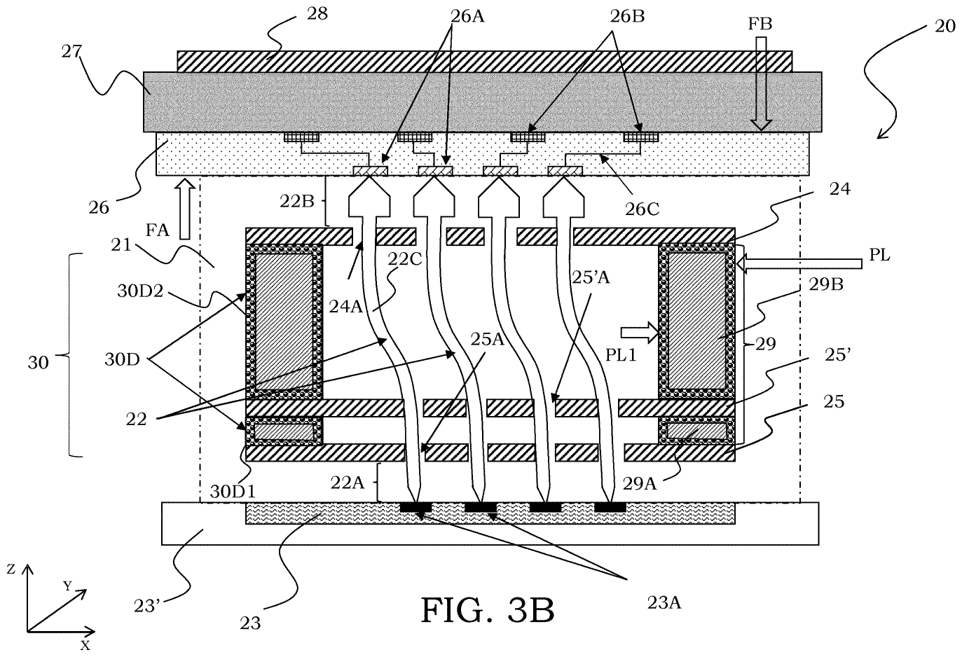

In this case, the heat dispersion structure 30 comprises one lateral coating layer 30B made at the outer lateral portion PL of the probe head 21, in particular at a lateral wall of the housing element 29 opposite the contact probes 22, i.e., an outer lateral wall of the housing element 29, as schematically shown in FIG. 3A. In this way, the lateral coating layer 30B forming the heat dispersion structure 30 is exposed to the air of the environment surrounding the probe head 21.

The lateral coating layer 30B, as the coating layer 30A of the examples illustrated in FIGS. 2A-2D, is made of a high thermal conductivity material λ, namely greater than 100 W/(m·K), preferably greater than 500 W/(m·K), and preferably with a high electrical resistivity ρ, namely greater than 10⁴ Ω·m, preferably greater than 10¹⁶ Ω·m, such as silicon nitride, silicon carbide and CVD-D (Chemical Vapor Deposition-Diamond), as above indicated for the other embodiments.

Said lateral coating layer 30B has a thickness H2 according to the x axis of the local reference of FIG. 3A, i.e., in a direction parallel to the development plane π of the device under test 23 and to the guides, comprised between 50 and 1000 microns, preferably 500 microns.

According to an alternative embodiment, schematically illustrated in FIG. 3B, the heat dispersion structure 30 may comprise at least one full covering layer 30D of the housing element 29, in particular a first covering layer 30D1 of a first portion 29A of the housing element 29 arranged between the intermediate guide 25′ and the lower guide 25 and a second covering layer 30D2 of a second portion 29B of the housing element 29 arranged between the intermediate guide 25′ and the upper guide 24, said covering layers 30D1 and 30D2 extending along all of the walls of the portions of the housing element 29, entirely covering them and thus being exposed to the air of the environment surrounding the probe head 21 at the outer lateral portion PL thereof but also to the air inside the probe head 21, at a further internal lateral portion PL1 of the housing element 29.

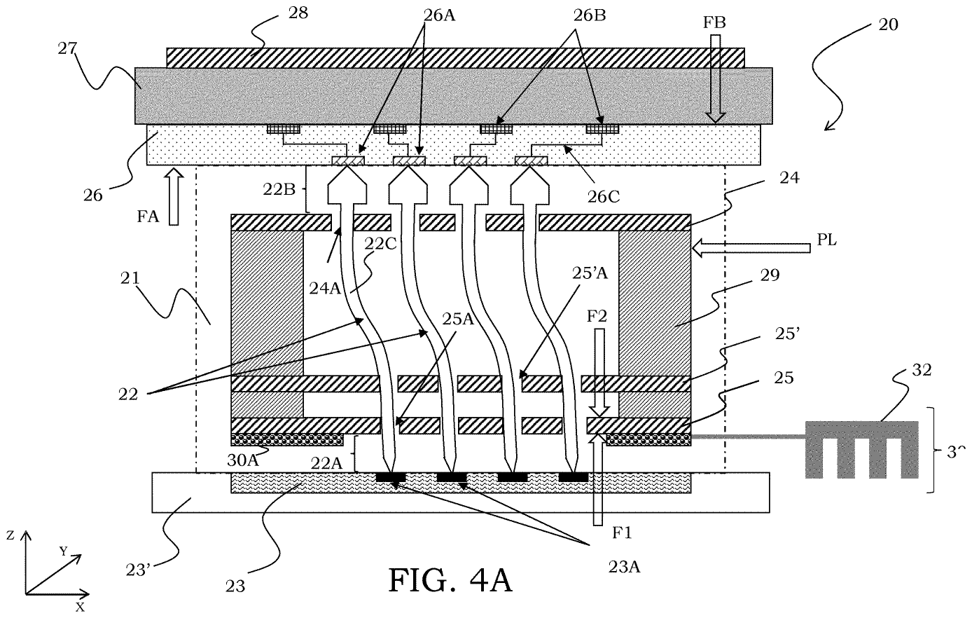

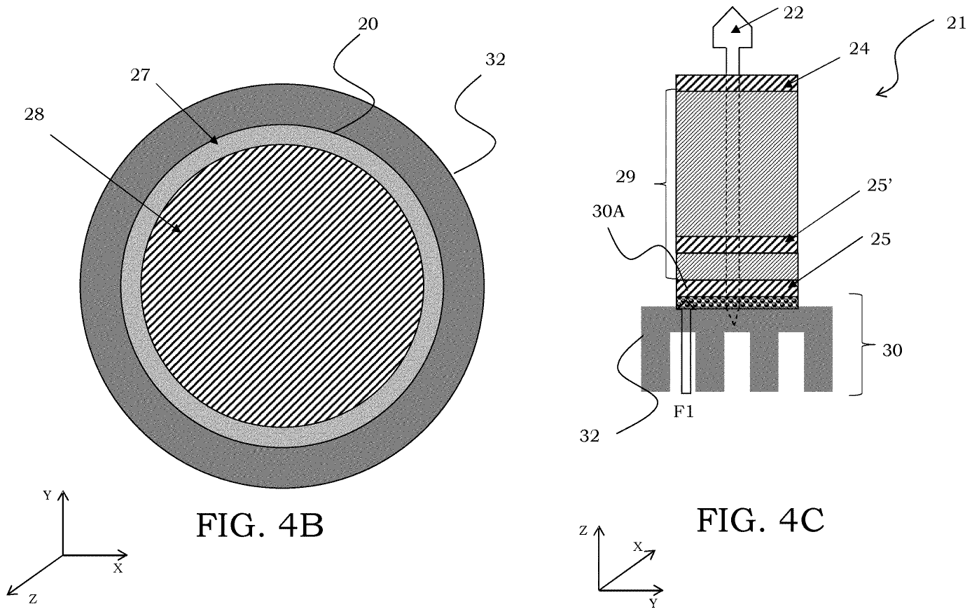

In an advantageous alternative embodiment, the heat dispersion structure 30 may comprise an outer heat dissipator 32, as schematically illustrated in FIG. 4A starting from the embodiment of FIG. 2A, i.e., with a heat dispersion structure 30 comprising a coating layer 30A arranged on a lower face F1 of the lower guide 25. It is pointed out that in this case the coating layer 30A essentially provides for the collection of the heat produced inside the probe head 21 whereas the heat dissipator 32 is mainly responsible for the dissipation thereof, preferably in air. It is obviously possible to use an outer heat dissipator 32 even in a probe head 21 made according to the embodiments of FIGS. 2B-2D.

Suitably, as shown in the top and side views of FIGS. 4B and 4C, said heat dissipator 32 may be comb-shaped, namely may be equipped with a plurality of wings able to increase the heat dissipation and be arranged below the probe head 21, for instance at a peripheral portion thereof outside the active zone of the lower guide 25 provided with the coating layer 30A.

In this way, it is possible to advantageously use a heat dissipator 32 of the metallic type, for instance of aluminum or copper, i.e., low-cost materials that ensure good heat dissipation, also thanks to the comb-conformation of said heat dissipator 32.

The heat dissipator 32 thus makes it extremely effective the dissipation of the heat produced inside the probe head 21 and collected by the coating layer 30A, in particular in the air of the environment surrounding the probe head 21.

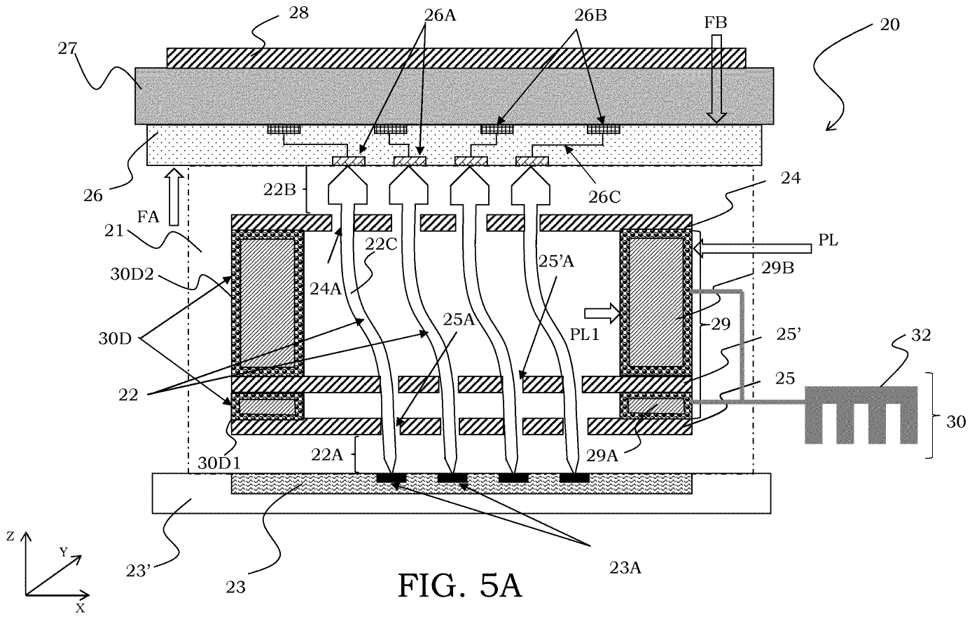

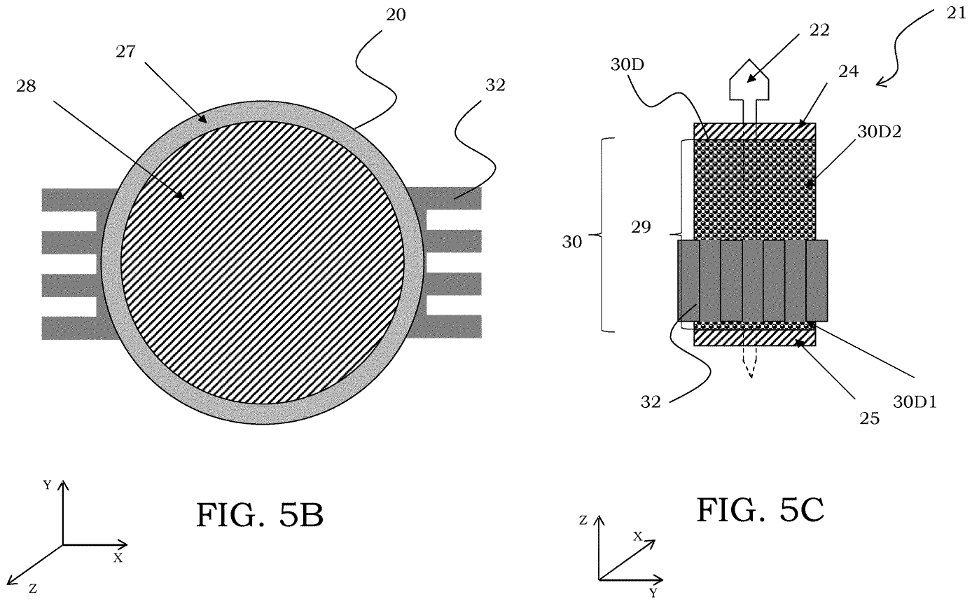

In an alternative embodiment schematically illustrated in FIGS. 5A-5D, the probe card 20 comprises a probe head 21 according to the embodiment of FIG. 3B, namely with a heat dispersion structure 30 associated with the housing element 29 and equipped with a full covering layer 30D comprising respective covering layers 30D1 and 30D2 of the first and second portions 29A and 29B of the housing element 29. The heat dispersion structure 30 further comprises a heat dissipator 32 thermally associated with said full covering layer 30D. Obviously it is possible to use a heat dissipator 32 associated with the housing element 29 even in a probe head 21 made according to the embodiment of FIG. 3A.

In particular, it is possible to make said heat dissipator 32 so as to peripherally surround the housing element 29 and be thermally in contact with both the portions thereof and thus with both the covering layers 30D1 and 30D2.

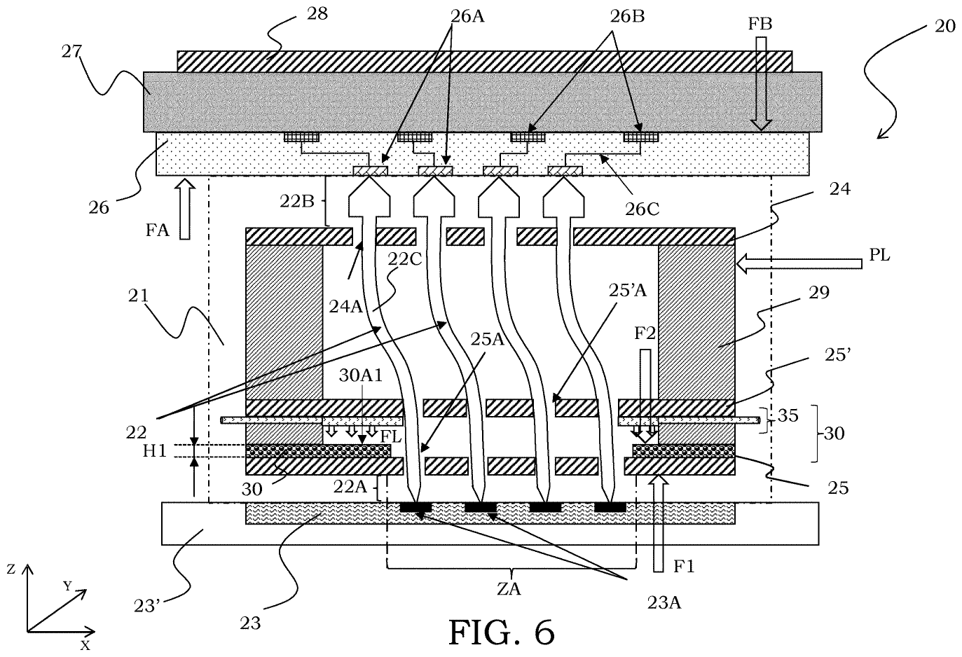

Furthermore, according to an alternative embodiment illustrated in FIG. 6 starting from the embodiment of FIG. 2C, the heat dispersion structure 30 of the probe head 21 further comprises a forced-air supply structure 35 adapted to convey air into the probe head 21, in particular at the coating layer 30A of the heat dispersion structure 30, so as to improve the dissipation in air of the heat produced by the probe head 21 and collected by said coating layer 30A, already inside the probe head 21 itself. Even in this case, it is possible to use said forced-air supply structure 35 even in a probe head 21 made according to the embodiments of FIGS. 2B-2D.

Suitably, the forced-air supply structure 35 produces a forced-air flow FL inside the probe head 21.

In particular, said forced-air flow FL is sent to the portion 30A1 of the coating layer 30A exposed to air inside the probe head 21, however without extending at the active zone ZA, so as not to interfere with the operation of the contact probes 22.

In an alternative embodiment not illustrated, the probe card 20 including the probe head 21 may also comprise an additional heat dispersion device equipped with at least one active or passive thermal pipe in thermal contact with the space transformer 26 to aid the dispersion of the heat generated inside the probe head during the operation thereof.

In conclusion, advantageously according to the invention, a probe head equipped with a structure able to disperse the possible heat produced by the test operations of an integrated device, in particular in case of power signals, is obtained.

In this way, the probe card comprising the probe head according to the present invention is suitable for applications in which the test operations significantly heat the probe card as a whole, thus ensuring a correct operation thereof and avoiding, thanks to the dispersion of heat made by the heat dispersion structure associated with the probe head, any deformation of the elements that make up said card, deformation which could affect the proper outcome of the test operations.

The heat dispersion is further improved in the event the heat dispersion structure is associated with an outer heat dissipator or with a forced-air supply structure.

Obviously, a person skilled in the art, in order to meet contingent and specific requirements, may make to the above-described probe head and probe card numerous modifications and variations, all included in the scope of protection of the invention as defined by the following claims.

1. A probe head comprising:
a guide provided with a plurality of guide holes;
a plurality of contact probes housed in the plurality of guide holes and configured to abut onto a plurality of contact pads of a device under test,
a housing element configured to enclose the contact probes, and
heat dispersion structure configured to collect and dissipate heat produced by the probe head and by the contact probes therein contained during the test operations of the electronic device,
wherein the heat dispersion structure comprises a layer having a thermal conductivity greater than 100 W/(m·K).

2. The probe head according to claim 1, wherein the layer is selected from the group consisting of: a coating layer arranged along a face of the guide, a lateral coating layer of the housing element, a covering layer of the guide that comprises a lateral portion extending along a lateral wall of the guide and a planar portion extending along a further face of the guide, the further face being orthogonal to the lateral wall, and a full covering layer of the housing element.

3. The probe head according to claim 1, wherein the layer comprises a portion in contact with air.

4. The probe head according to claim 1, wherein the layer is made of a material having thermal conductivity greater than 500 W/(m·K).

5. The probe head according to claim 1, wherein the layer is made of a material having an electrical resistivity greater than 10⁴ Ω·m.

6. The probe head according to claim 1, wherein the layer is made of a material selected from a group consisting of: silicon nitride, silicon carbide and CVD-D (Chemical Vapor Deposition-Diamond).

7. The probe head according to claim 1, wherein the layer is formed in correspondence of a face of the guide outside an active zone of the guide, the active zone comprising guide holes for housing the contact probes.

8. The probe head according to claim 1, wherein the layer has a thickness between 50 and 500 microns.

9. The probe head according to claim 1, wherein the layer is formed in correspondence of a face of the guide even in correspondence of an active zone of the guide, the active zone comprising guide holes for housing the contact probes, and wherein the probe head is provided with electrical decoupling structures between the contact probes and the layer selected from the group consisting of: a dielectric coating which covers portions of the contact probes in contact with the layer, clipping areas free from the layer along the edges of the guide holes for housing the contact probes.

10. The probe head according to claim 1, wherein the heat dispersion structure further comprises an outer heat dissipator thermally connected to the layer.

11. The probe head according to claim 10, wherein the heat dissipator peripherally surrounds the probe head.

12. The probe head according to claim 1, wherein the heat dispersion structure further comprises a forced-air supply structure adapted to convey air into the probe head.

13. The probe head according to claim 12, wherein the forced-air supply structure produces a forced-air flow in correspondence of the layer.

14. The probe head according to claim 12, wherein the forced-air supply structure produces a forced-air flow in correspondence of a portion of the layer outside an active zone of the guide, the active zone comprising guide holes for housing the contact probes.

15. A probe card configured to be mounted in a testing apparatus of electronic devices and comprising a probe head comprising:
a guide provided with a plurality of guide holes;
a plurality of contact probes housed in the plurality of guide holes and configured to abut onto a plurality of contact pads of a device under test,
a housing element configured to enclose the contact probes, and
a heat dispersion structure configured to collect and dissipate heat produced by the probe head and by the contact probes therein contained during the test operations of the electronic device,
wherein the heat dispersion structure comprises a layer having a thermal conductivity greater than 100 W/(m·K).

16. The probe card according to claim 15, wherein the heat dispersion device is provided with an active or passive thermal pipe in thermal contact with a space transformer of the said probe card to increase a dispersion of the heat generated inside the probe head during the operation thereof.

17. The probe card according to claim 15, wherein the layer is selected from the group consisting of: a coating layer arranged along a face of the guide, a lateral coating layer of the housing element, a covering layer of the guide that comprises a lateral portion extending along a lateral wall of the guide and a planar portion extending along a further face of the guide, the further face being orthogonal to the lateral wall, and a full covering layer of the housing element.

18. The probe card according to claim 15, wherein the layer selected from the group consisting of: a layer comprising a portion in contact with air, a layer made of a material having thermal conductivity greater than 500 W/(m·K), a layer made of a material having an electrical resistivity greater than 10⁴ Ω·m, a layer made of a material selected from the group consisting of: silicon nitride, silicon carbide and CVD-D (Chemical Vapor Deposition-Diamond), a layer formed in correspondence of a face of the guide outside an active zone of the guide, the active zone comprising guide holes for housing the contact probes, a layer having a thickness between 50 and 500 microns.

19. The probe card according to claim 15, wherein the layer is formed in correspondence of a face of the guide even in correspondence of an active zone of the guide, the active zone comprising guide holes for housing the contact probes, and wherein the probe head is provided with electrical decoupling structures between the contact probes and the layer selected from the group consisting of: a dielectric coating which covers portions of the contact probes in contact with the layer, clipping areas free from the layer along the edges of the guide holes for housing the contact probes.

20. The probe card according to claim 1, wherein the heat dispersion structure is selected from the group consisting of a heat dispersion structure further comprising an outer heat dissipator thermally connected to the layer, a heat dissipator peripherally surrounding the probe head, a heat dispersion structure further comprising a forced-air supply structure adapted to convey air into the probe head, a heat dispersion structure further comprising a forced-air supply structure adapted to convey air into the probe head wherein the forced-air supply structure produces a forced-air flow in correspondence of the layer, a heat dispersion structure further comprising a forced-air supply structure adapted to convey air into the probe head wherein the forced-air supply structure produces a forced-air flow in correspondence of a portion of the layer outside an active zone of the guide, the active zone comprising guide holes for housing the contact probes.
